(19) United States
(12) Patent Application Publication
(10) Pub. No.: US 2016/0360622 A1
(43) Pub. Date: Dec. 8, 2016

(54) Integrated Circuit With Sensor Printed In Situ

(71) Applicant: Microchip Technology Incorporated, Chandler, AZ (US)

(72) Inventors: Randy L. Yach, Phoenix, AZ (US); Arthur B. Eck, Gilbert, AZ (US)

(73) Assignee: Microchip Technology Incorporated, Chandler, AZ (US)

(21) Appl. No.: 15/169,456

(22) Filed: May 31, 2016

Related U.S. Application Data
(60) Provisional application No. 62/169,986, filed on Jun. 2, 2015.

(51) Int. Cl. H05K 3/34

(52) U.S. Cl. CPC H05K 3/341; H05K 2201/10151; H05K 2201/10287; H05K 2203/049; H05K 2203/043; B23K 1/0016

(57) ABSTRACT

The present disclosure teaches a method for manufacturing a module comprising an integrated circuit and a sensor. The method may comprise: mounting an integrated circuit (IC) die on a printed circuit board (PCB) using a high temperature process to provide an electrical connection between interconnects of the PCB and the die; and printing a sensor directly onto the module after all high temperature mounting processes are complete.

### RELATED PATENT APPLICATION

This application claims priority to commonly owned U.S. Provisional Patent Application No. 62/169,986 filed Jun. 2, 2015, which is hereby incorporated by reference herein for all purposes.

### TECHNICAL FIELD

The present disclosure relates to integrated circuits, and specifically integrated circuits with sensors printed in situ thereon.

### BACKGROUND

Surface mount technology refers to methods for producing electronic circuits in which various components are mounted on the surface of a printed circuit board (PCB). Such a circuit may be called a surface mount device. Surface mount methods may be preferred in place of “through-hole” mounting techniques because they allow mounting smaller components on both sides of the PCB and increased component density, both of which reduce the overall size, and may be simpler to automate.

Many sensors that would be otherwise useful with integrated circuits (IC) are compromised by the solder reflow or wave solder processes employed in surface mounting. For example, some sensors used to detect chemicals may be damaged if subjected to high temperature. If a temperature-sensitive sensor is to be mounted on a printed circuit board (PCB), it must be connected after soldering is complete. This post-soldering step, sometimes referred to as one or more “secondary attachment” processes, entails additional cost and time requirements.

In addition, secondary attachment processes result in increased physical distance between the sensor and the signal processing apparatus (e.g., an IC chip or die) when compared to sensors that are placed prior to the soldering step. Increased physical distance decreases the signal-to-noise ratio of the sensor output to the IC die. Reducing the physical distance between the two, therefore, would improve the performance of the sensors in a given application.

### SUMMARY

This summary is provided to introduce teachings of the present disclosure in a simplified form. The teachings are not limited to this summary, nor should the summary be read to limit the scope of the claimed subject matter.

According to some embodiments of the present disclosure, a method for manufacturing a module comprising an integrated circuit and a sensor may include: mounting an integrated circuit (IC) die on a printed circuit board (PCB) using a high temperature process to provide an electrical connection between interconnects of the PCB and the die; and printing a sensor directly onto the module after all high temperature mounting processes are complete.

In some embodiments, the IC die is enclosed in a housing comprising a top surface with a plurality of exposed contact areas providing electrical connections to the die enclosed in the housing. The method may include printing the sensor device directly onto the top surface of the housing.

In some embodiments, the IC die is enclosed in a housing comprising a top surface with an opening that exposes a portion of the IC die. The method may include printing the sensor device directly onto the exposed IC die.

In some embodiments, the IC die is enclosed in a housing comprising a top surface with an opening that exposes a portion of the IC die; and the exposed portion of the IC die includes a plurality of exposed electrical contact areas. The method may include printing the sensor device directly onto the exposed IC die.

In some embodiments, the IC die is enclosed in a housing comprising a top surface with an opening that exposes a portion of the IC die and the exposed portion of the IC die includes a plurality of exposed electrical contact areas. The method may include printing the sensor device directly onto the exposed electrical contact areas.

In some embodiments, the IC die is enclosed in a housing comprising a top surface with an opening that exposes a portion of the IC die and the exposed portion of the IC die includes a plurality of exposed electrical contact areas. The method may include printing the sensor device directly onto the IC die and connecting the sensor to the IC die by wire bonding.

Some embodiments may include printing the sensor device directly onto the PCB.

The teachings of the present disclosure provide a method for joining a sensor device to an integrated circuit. The example method may include providing an integrated circuit (IC) die at least partially enclosed in a housing comprising a top surface; and printing the sensor device directly onto the top surface of the housing.

In some embodiments, the top surface of the housing defines a plurality of exposed contact areas providing electrical connections to the IC die; and the method includes printing the sensor device directly onto the exposed contact areas of the IC die.

In some embodiments, top surface of the housing defines an opening that exposes a portion of the IC die; and the method includes printing the sensor device directly onto the exposed IC die.

In some embodiments, the top surface of the housing defines an opening that exposes a portion of the IC die and the exposed portion of the IC die includes a plurality of exposed electrical contact areas, The example method may include printing the sensor device directly onto the IC die; and connecting the sensor to the IC die by wire bonding.

Some embodiments may include mounting the IC die to a printed circuit board with a high temperature mounting process before printing the sensor device.

In some embodiments, the high temperature mounting process includes a soldering process, a reflow soldering process, or a wave soldering process.

### BRIEF DESCRIPTION OF THE DRAWINGS

FIG. 1 is a drawing showing an example sensor module according to teachings of the present disclosure.

FIG. 2 is a drawing showing an example sensor module according to teachings of the present disclosure.

FIGS. 3A and 3B are drawings illustrating an example sensor module before and after printing a sensor thereon, according to teachings of the present disclosure.

FIGS. 4A and 4B are drawings showing an example sensor module before and after printing a sensor on the encapsulated IC die, according to teachings of the present disclosure.

FIGS. 5A and 5B are drawings illustrating an example sensor module before and after printing a sensor thereon, according to teachings of the present disclosure.

FIG. 6 is a flowchart showing an example method for manufacturing a module comprising an integrated circuit and a sensor, according to teachings of the present disclosure.

FIG. 7 is a flowchart showing an example method for manufacturing a module comprising an integrated circuit and a sensor, according to teachings of the present disclosure.

The figures provide illustrations of various embodiments of the teachings of the present disclosure. A person having ordinary skill in the art will be able to use the teachings of the present disclosure to develop alternative embodiments of the structures and methods depicted in the figures without departing from the scope of the claims or the teachings of the present disclosure.

### DETAILED DESCRIPTION

Embodiments of the present disclosure and their advantages over the prior art may be best understood by reference to the Figures described below.

Various assembly techniques may be used to surface mount an IC die to a PCB. The PCB normally has a plurality of leads to allow electrical connection to the leads of the IC die. Solder paste may be applied to the PCB using a screen printing and/or stencil process. In automated systems, the components to be mounted may be placed by “pick-and-place” machines.

The PCBs, along with the various components, may be placed in a reflow soldering oven. The oven may raise the temperature of the PCB, the components, and the solder paste. When the temperature reaches the melting point of the solder particles in the solder paste, the component leads are thereby bonded to the contact points on the PCB. In some systems, the temperature is raised using infrared lamps. In other systems, hot gas convection may use air and/or nitrogen gas. In another alternative, vapor phase reflow may use fluorocarbon liquids with high boiling points.

In some devices, once an IC component is mounted to a PCB, it may be further packaged for protection from mechanical damage, thermal damage, radio frequency noise emission, electrostatic discharge, etc. Some devices may include “glob-top” or “glop-top” packaging. Glob-top coating may include a drop of epoxy or resin deposited over the IC die or chip and any leads or connections to the PCB, after the IC die has been connected to the PCB (e.g., by soldering). Glob-top coating may be appropriate for IC dies mounted directly to a PCB, sometimes called “chip-on-board” (COB) mounting.

In other devices, an IC die may be encapsulated in a plastic housing before mounting to the PCB. Various standardized packages may be used, including as examples, dual-in-line, quad-in-line, grid arrays, small outline transistors, etc. Such ICs may be called encapsulated or packaged.

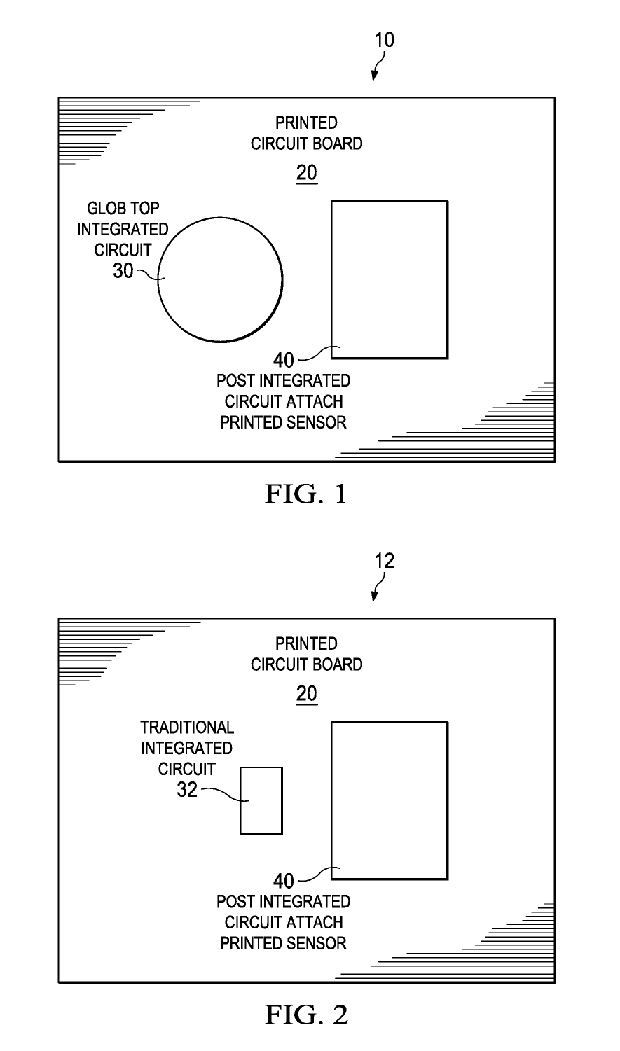

FIG. 1 is a drawing showing an example sensor module 10 according to teachings of the present disclosure. The embodiment shown includes a COB IC die 30 surface mounted to a PCB 20 and then coated with a glob-top epoxy, along with a sensor 40 printed onto the PCB 20 after the surface mounting process was completed. PCB 20 may include various leads, circuitry, etc. to provide appropriate electrical communication between IC die 30 and sensor 40.

FIG. 2 is a drawing showing an example sensor module 12 according to teachings of the present disclosure. The embodiment shown includes an encapsulated IC die 32 surface mounted to a PCB 20, along with a sensor 40 printed onto the PCB 20 after the surface mounting process was completed. PCB 20 may include various leads, circuitry, etc., to provide appropriate electrical connections between IC die 32 and sensor 40.

In some embodiments, such as those shown in FIGS. 1 and 2, sensor 40 may include a chemical and/or gas sensor. Various types of sensors may be manufactured by printing processes. For example, glucose sensors for the treatment of diabetes are generally manufactured using a printing process. Other examples include biosensors, capacitive sensors, piezoresistive sensors, piezoelectric sensors, photodetectors, temperature sensors, humidity sensors, and gas sensors. Example printing processes include screen printing (e.g., “thick film” processes), pad printing, additive manufacturing, PiezoPaint, and/or selective sintering processes.

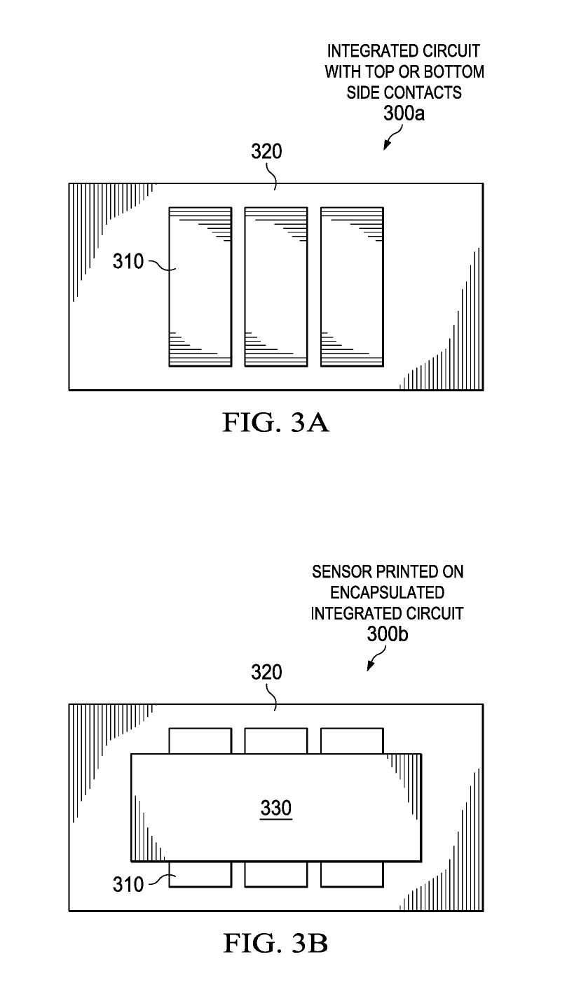

FIGS. 3A and 3B are drawings illustrating an example sensor module 300 before (300a) and after (300b) printing a sensor 330 thereon, according to teachings of the present disclosure.

Sensor module 300a may include an encapsulated IC 320 with exposed body surface contacts 310. In the example shown, there are three top surface contacts, but the teachings of the present disclosure may be practiced with any appropriate number of surface contacts. In general, the exposed body surface contacts 310 may be on the opposite side of the encapsulated IC 320 from any leads and/or mounting features which will be used to connect IC 320 to a PCB (not shown in FIGS. 3A and 3B). While the integrated circuit die is encapsulated within the housing 320, the contact areas 310 may provide an available electrical connection to the encapsulated die.

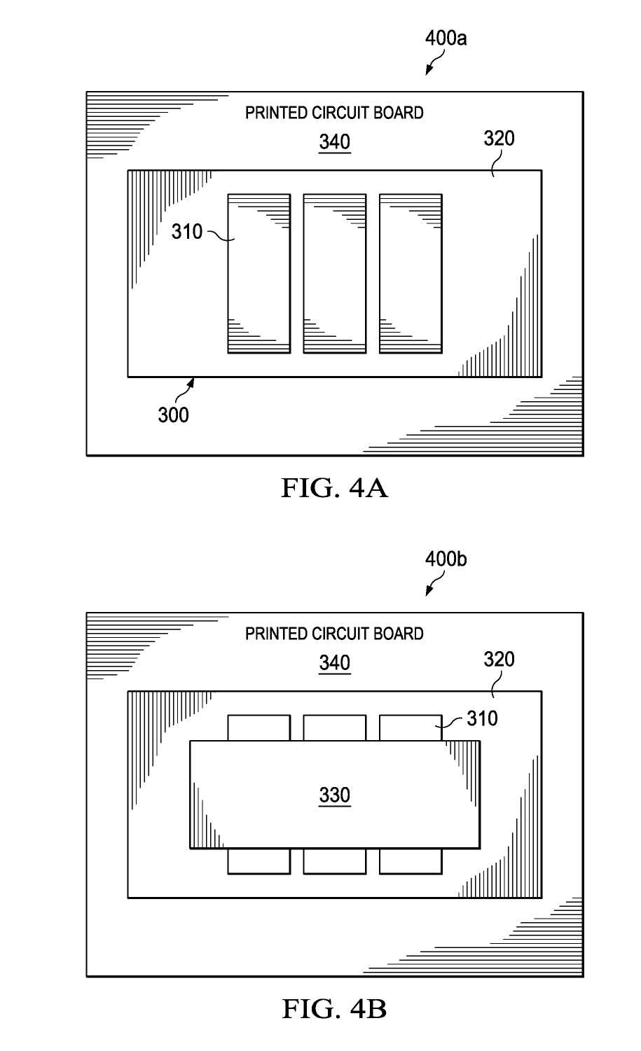

Then, the sensor 330 may be printed on top of the encapsulated IC 320 thereby connecting to the top surface contacts as shown in FIG. 3B. Sensor module 300b may then be attached to a printed circuit board, module, etc. providing a sensor module similar to that shown in FIG. 4B, including a sensor module including encapsulated IC die 320 with exposed body surface contacts 310 and sensor 330 printed thereon. The entire module 300b may be attached to a socket on the printed circuit board 300. Use of a socket may avoid exposure to high temperatures that would occur during a surface mounting/soldering procedure, for example.

FIGS. 4A and 4B are drawings showing an example sensor module 400 before (400a) and after (400b) printing a sensor 330 on the encapsulated IC die 320, according to teachings of the present disclosure. Encapsulated die 320 may be mounted to PCB 340 using a surface mount/soldering technique, in contrast to the embodiments shown in FIGS. 3A and 3B, because sensor 330 is not yet present as shown in FIG. 4A. Encapsulated IC 320 may include exposed body surface contacts 310. In the example shown, there are three top surface contacts, but the teachings of the present disclosure may be practiced with any appropriate number of surface contacts. In general, the exposed body surface contacts 310 may be on the opposite side of the encapsulated IC 320 from any leads and/or mounting features which were used to connect IC 320 to a PCB 340. While the integrated circuit die is encapsulated within the housing 320, the contact areas 310 may provide an available electrical connection to the encapsulated die.

Then, the sensor 330 may be printed on top of the encapsulated IC 320 thereby connecting to the top surface contacts as shown in FIG. 4B. Sensor module 400b then operates normally in electrical connection to PCB 340 and IC 320.

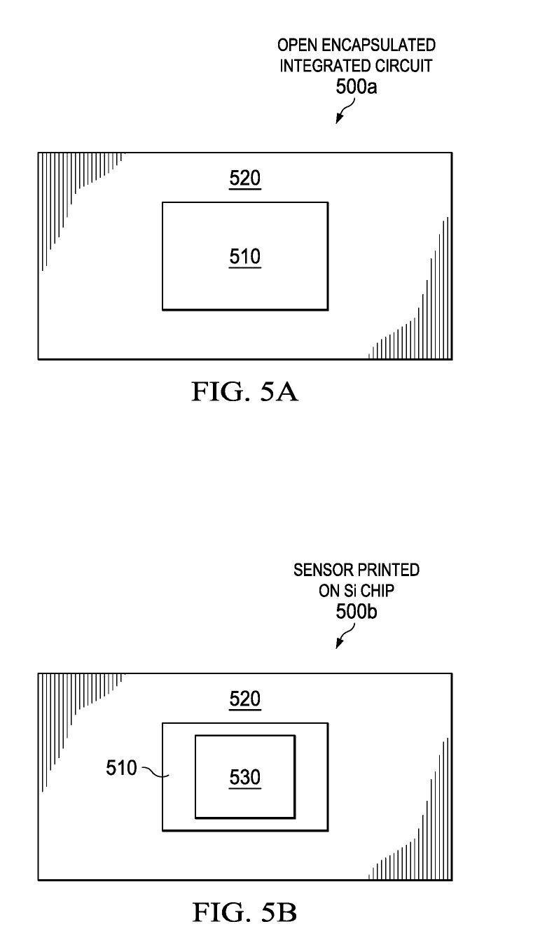

FIGS. 5A and 5B are drawings illustrating an example sensor module 500 before (500a) and after (500b) printing a sensor 530 thereon, according to teachings of the present disclosure. Sensor module 500a may include an encapsulated IC 520 with an opening 510 exposing a portion of the IC die within. In general, the exposed portion 510 of the IC die may be on the opposite side of the encapsulated IC 520 from any leads and/or mounting features which will be used to connect IC 520 to a PCB (not shown in FIGS. 5A and 5B). While the integrated circuit die is encapsulated within the housing 520, the exposed area 510 may provide an available electrical connection to the encapsulated die.

Then, the sensor 530 may be printed on top of the encapsulated IC 520 thereby connecting to the top surface contacts as shown in FIG. 5B. According to other embodiments, bonding wires may be used to couple the printed sensor 530 with the exposed die. The opening 520 may be designed to stay open to provide an exposure of the printed sensor 530 to the environment. However, according to some embodiments, the opening may also be closed for sensors that do not require exposure, for example certain temperature sensors.

Sensor module 500b may then be attached to a printed circuit board, module, etc. providing a sensor module including encapsulated IC die 520 with exposed portion 510 and sensor 530 printed thereon. The entire module 500b may be attached to a socket on the printed circuit board. Use of a socket may avoid exposure to high temperatures that would occur during a surface mounting/soldering procedure, for example.

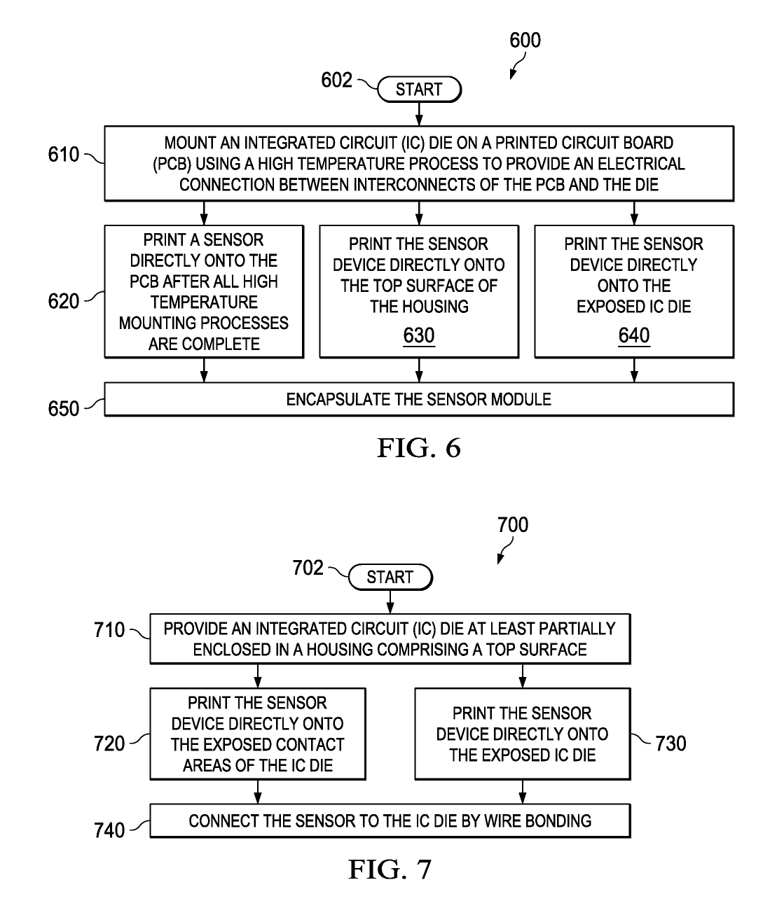

FIG. 6 is a flowchart showing an example method 600 for manufacturing a module comprising an integrated circuit and a sensor. Persons having ordinary skill in the art will be able to alter the order of some steps of method 600 and leave others out completely without departing from the scope of the teachings of the present disclosure.

At Step 602, method 600 begins.

Step 610 includes mounting an IC die on a PCB using a high temperature process to provide an electrical connection between interconnects of the PCB and the die. Step 610 may include any appropriate surface mounting process. The IC die may be unencapsulated, fully encapsulated, or partially encapsulated. Depending on the type of packaging for the IC die, method 600 may include any of Steps 620, 630, or 640.

Step 620 includes printing a sensor directly onto the PCB after all high temperature mounting processes are complete. Step 620 may be appropriate for glob-top IC dies or fully encapsulated dies with no available connections for the sensor, such as the embodiments shown in FIGS. 1 and 2. In some embodiments, the IC die may have exposed portions but the sensor may be printed directly onto the PCB because of the size and/or spacing needs for the IC die and/or the sensor.

Step 630 includes printing the sensor device directly onto a top surface of the housing or an encapsulated die. Step 630 may be appropriate for IC dies partially encapsulated with exposed contact areas, such as the embodiments shown in FIGS. 3A-4B.

Step 640 includes printing the sensor device directly onto the exposed IC die. Step 640 may be appropriate for IC dies only partially encapsulated with exposed portions of the IC die, sometimes called “open encapsulated ICs”, such as the embodiments shown in FIGS. 5A and 5B.

In method 600 as shown, all branches return to Step 650. Step 650 includes encapsulating the sensor module. The sensor may be encapsulated and/or left exposed depending on the form and function of the sensor. For example, temperature sensors may be encapsulated while gas and/or chemical sensors may be left exposed to the surrounding atmosphere.

FIG. 7 is a flowchart showing an example method 700 for manufacturing a module comprising an integrated circuit and a sensor. Persons having ordinary skill in the art will be able to alter the order of some steps of method 700 and leave others out completely without departing from the scope of the teachings of the present disclosure.

At Step 702, method 700 begins.

Step 710 includes providing an IC die at least partially enclosed in a housing comprising a top surface. The IC die may be fully encapsulated or partially encapsulated. Depending on the type of packaging for the IC die, method 700 may include Step 720 or 730.

Step 720 includes printing the sensor device directly onto the exposed contact areas of the IC die. Step 720 may be appropriate for IC dies partially encapsulated with exposed contact areas, such as the embodiments shown in FIGS. 3A-4B.

Step 730 includes printing the sensor device directly onto the exposed IC die. Step 730 may be appropriate for IC dies only partially encapsulated with exposed portions of the IC die, sometimes called “open encapsulated ICs”, such as the embodiments shown in FIGS. 5A and 5B.

In method 700 as shown, all branches return to Step 740. Step 740 includes connecting the sensor to the IC die by wire bonding. Step 740 may not be necessary if the sensor device is printed in such a manner that the connections are made by the printing process.

In some embodiments of method 700, the sensor module may be mounted on a PCB without using a high temperature process, thereby providing an electrical connection between interconnects of the PCB and the die. For example, the sensor module may be plugged into a socket on the PCB.

What is claimed:

1. A method for manufacturing a module comprising an integrated circuit and a sensor, the method comprising:
mounting an integrated circuit (IC) die on a printed circuit board (PCB) using a high temperature process to provide an electrical connection between interconnects of the PCB and the die; and
printing a sensor directly onto the module after all high temperature mounting processes are complete.

2. A method according to claim 1, wherein the IC die is enclosed in a housing comprising a top surface with a plurality of exposed contact areas providing electrical connections to the die enclosed in the housing; and
wherein the method further comprises printing the sensor device directly onto the top surface of the housing.

3. A method according to claim 1, wherein the IC die is enclosed in a housing comprising a top surface with an opening that exposes a portion of the IC die; and
wherein the method further comprises printing the sensor device directly onto the exposed IC die.

4. A method according to claim 1, wherein:
the IC die is enclosed in a housing comprising a top surface with an opening that exposes a portion of the IC die; and
the exposed portion of the IC die includes a plurality of exposed electrical contact areas; and
wherein the method further comprises printing the sensor device directly onto the exposed IC die.

5. A method according to claim 1, wherein:
the IC die is enclosed in a housing comprising a top surface with an opening that exposes a portion of the IC die; and
the exposed portion of the IC die includes a plurality of exposed electrical contact areas; and
wherein the method further comprises printing the sensor device directly onto the exposed electrical contact areas.

6. A method according to claim 1, wherein:
the IC die is enclosed in a housing comprising a top surface with an opening that exposes a portion of the IC die; and
the exposed portion of the IC die includes a plurality of exposed electrical contact areas; and
wherein the method further comprises:
printing the sensor device directly onto the IC die; and
connecting the sensor to the IC die by wire bonding.

7. A method according to claim 1, further comprising printing the sensor device directly onto the PCB.

8. A method for joining a sensor device to an integrated circuit, the method comprising:
providing an integrated circuit (IC) die at least partially enclosed in a housing comprising a top surface; and
printing the sensor device directly onto the top surface of the housing.

9. A method according to claim 8, wherein the top surface of the housing defines a plurality of exposed contact areas providing electrical connections to the IC die; and
wherein the method includes printing the sensor device directly onto the exposed contact areas of the IC die.

10. A method according to claim 8, wherein top surface of the housing defines an opening that exposes a portion of the IC die; and
wherein the method includes printing the sensor device directly onto the exposed IC die.

11. A method according to claim 8, wherein the top surface of the housing defines an opening that exposes a portion of the IC die and the exposed portion of the IC die includes a plurality of exposed electrical contact areas; further comprising:
printing the sensor device directly onto the IC die; and
connecting the sensor to the IC die by wire bonding.

12. A method according to claim 8, further comprising mounting the IC die to a printed circuit board with a high temperature mounting process before printing the sensor device.

13. A method according to claim 8, further comprising mounting the IC die to a printed circuit board with a high temperature mounting process before printing the sensor device; and
wherein the high temperature mounting process includes a soldering process, a reflow soldering process, or a wave soldering process.
